(19) United States
(12) Patent Application Publication
(10) Pub. No.: US 2013/0167588 A1
(43) Pub. Date: Jul. 4, 2013

(54) SHEET WAFER FURNACE WITH GAS PRESERVATION SYSTEM

(71) Applicants: Steven Sherman, Newton, MA (US); Leo van Glabbeek, Franklin, MA (US); Stephen Yamartino, Wayland, MA (US)

(72) Inventors: Steven Sherman, Newton, MA (US); Leo van Glabbeek, Franklin, MA (US); Stephen Yamartino, Wayland, MA (US)

(21) Appl. No.: 13/570,885

(22) Filed: Aug. 9, 2012

Related U.S. Application Data
(60) Provisional application No. 61/529,101, filed on Aug. 30, 2011.

(51) Int. Cl. H01L 21/02

(52) U.S. Cl. CPC H01L 21/02005
USPC 65/32.5; 65/193; 65/157; 65/172; 65/203; 65/90

(57) ABSTRACT

A sheet wafer furnace has a chamber having an opening, and a crucible, within the chamber, and spaced from the opening. The furnace also has a puller configured to pull a sheet wafer from molten material in the crucible and through the opening in the chamber, and a seal across the opening of the chamber.

### RELATED APPLICATIONS

This application claims benefit of the earlier filing data under 35 U.S.C. §119(e) of U.S. Provisional Application Ser. No. 61/529,101 filed Aug. 30, 2011, entitled “Sheet Wafer Furnace with Gas Preservation System,” the entirety of which is incorporated herein by reference.

### FIELD OF THE INVENTION

The invention generally relates to sheet wafers and, more particularly, the invention relates to preserving process gasses in a sheet wafer fabrication process.

### BACKGROUND OF THE INVENTION

Silicon wafers are the building blocks of a wide variety of semiconductor devices, such as solar cells, integrated circuits, and MEMS devices. For example, Evergreen Solar, Inc. of Marlboro, Mass. forms solar cells from silicon wafers fabricated by means of the well-known “ribbon pulling” technique.

The ribbon pulling technique forms sheet wafers within a chamber having a crucible of molten silicon, and a puller to draw a sheet wafer from the crucible and out of the chamber. This process requires that the chamber be substantially free of contaminants, such as oxygen, which can oxidize and otherwise contaminate the newly formed sheet wafers. Accordingly, furnaces forming sheet wafers typically fill the chamber with a selected gas, such as argon, to prevent oxygen or other contaminants from contacting the growing wafers.

Although it is the preferred gas for this sheet wafer growth, argon has a number of drawbacks. Primarily, it is in short supply. In fact, in some regions, the supply of argon is less than the amount required by a reasonably sized wafer fabrication plant. This shortage undesirably can impact the total number of sheet wafers that can be produced, and increase overall wafer cost.

### SUMMARY OF THE INVENTION

In accordance with one embodiment of the invention, a sheet wafer furnace has a chamber having an opening, and a crucible, within the chamber, and spaced from the opening. The furnace also has a puller configured to pull a sheet wafer from molten material in the crucible and through the opening in the chamber, and a seal across the opening of the chamber.

The seal may include a first set of flaps that cooperate to form a first seal. In addition, the seal may also have a second set of flaps that cooperate to form a second seal, where the second set of flaps is closer to the crucible than the first set of flaps. The first set of flaps and the second set of flaps may form a void therebetween when the first and second seal are closed. Accordingly, the void may contain a gas, such as nitrogen. In either case, the flaps may be flexible (e.g., they could include polyimide).

Some embodiments include a cartridge that includes the seal. To simplify maintenance of the furnace, the cartridge may be removably connectible across the opening. Moreover, the furnace also may have a movable hinge secured to open the seal. The hinge may be coupled with a motor configured to control opening and closing of the seal, or it may be manually movable. The seal may include any of a number of seals, such as a tent seal.

To facilitate wafer fabrication, the furnace may include a wafer guide spaced from the top surface of the crucible and within the chamber. The wafer guide may form a channel for passing a growing sheet wafer. In addition, the furnace may include an afterheater region for controlling the temperature within the interior chamber. The wafer guide may be at least in part positioned within the afterheater region. Alternatively, the wafer guide may include a plurality of posts extending from at least two opposing surfaces of the afterheater.

The seal may include members on two sides of the opening that each provide a generally radially inward force at a contact point. The members preferably apply a net neutral force at the contact point.

In accordance with another embodiment, a method of growing a sheet wafer melts molten material in a crucible within a chamber having an opening, and draws a sheet wafer from the molten material in the crucible and through the opening. The opening has a seal that contacts two sides of the sheet wafer at a contact point on each side of the sheet wafer. Additionally, the seal forms a sliding seal along the sheet wafer.

In accordance with other embodiments, a method of forming a sheet wafer moves a growing wafer from molten material in a crucible in a growth chamber and adds a gas to the growth chamber. The gas has a substantially constant pressure within the growth chamber for a period of time. The method further recycles the gas while maintaining a substantially constant pressure. This embodiment may be implemented independently of other embodiments noted above, or in conjunction with the other embodiments noted above.

The method may use a buffer chamber in fluid communication with the growth chamber. In that case, the gas may travel from the growth chamber to the buffer chamber. Among others, the gas may include argon. Moreover, the method may direct the gas toward an argon recycling module.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a sheet wafer growth furnace configured in accordance with illustrative embodiments of the invention.

FIG. 2 schematically shows the furnace of FIG. 1 with one wall removed to show components within the internal chamber.

FIG. 3 schematically shows a tent seal module that at least partially seals a portion of the internal chamber of the furnace of FIGS. 1 and 2.

FIG. 4 schematically shows a cross-sectional view of the tent seal module of FIG. 3 across lines 4-4.

FIG. 5 schematically shows another embodiment of the tent seal module shown in FIG. 4.

FIG. 6 schematically shows a gas recycling system using the furnace of FIG. 1.

### DESCRIPTION OF ILLUSTRATIVE EMBODIMENTS

In illustrative embodiments, a sheet wafer furnace and process of forming sheet wafers preserve oxygen displacing gas injected within its growth chamber. To that end, the furnace may have a seal at one or more of the chamber openings used to remove cut sheet wafers. This seal, which may be a partial seal only, should reduce the amount of gas leaking from the growth chamber. In addition, the furnace may be part of a larger gas recycling system having a buffer chamber configured to ensure that the gas injected into its growth chamber maintains a substantially constant pressure. Details of illustrative embodiments are discussed below.

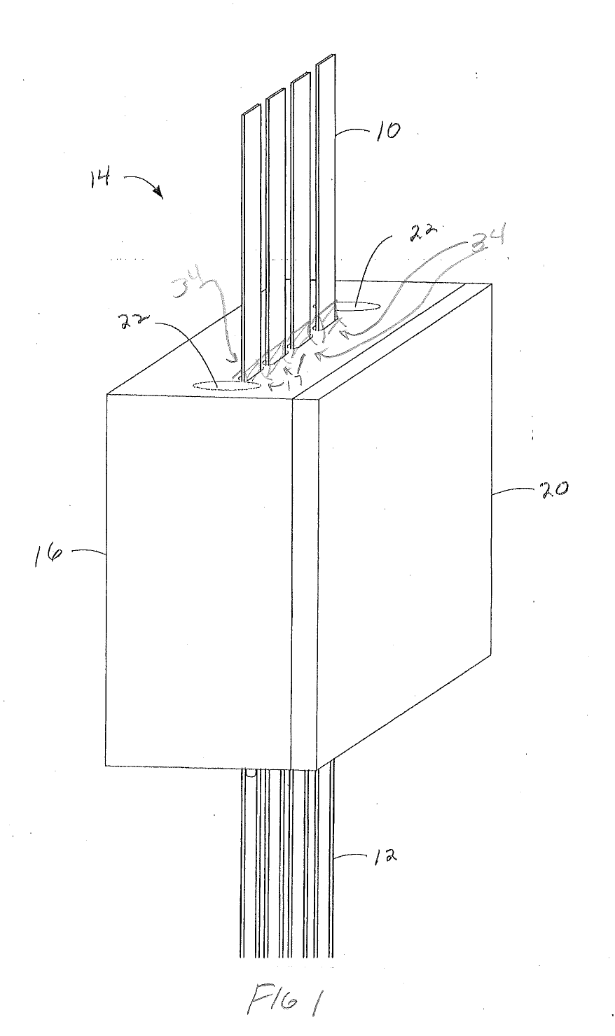

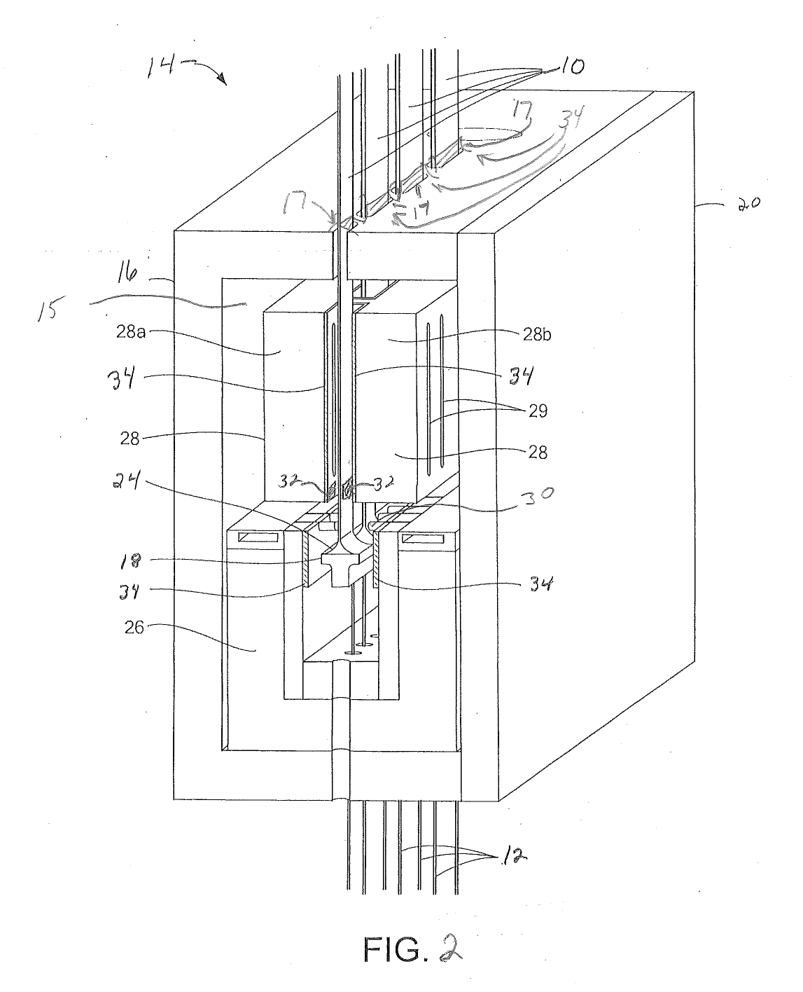

As known by those in the art, specially designed high temperature growth furnaces 14 form sheet wafers 10. A typical sheet wafer 10 may have a very thin body formed from polysilicon, and two high temperature filaments 12 forming its edges. FIG. 1 schematically shows a sheet wafer furnace 14 configured according to various embodiments of the invention. The furnace 14 may include a housing 16 forming an enclosed or sealed interior chamber (shown in FIG. 2 and referred to as a “growth chamber 15”). The growth chamber 15 preferably is substantially free of oxygen (e.g., to prevent combustion) and include one or more gases, such as argon or other inert gas, provided from an external gas source. The interior includes a resistively heated crucible 18 (shown in FIG. 2) for containing molten silicon, and other components for substantially simultaneously growing one or more silicon sheet wafers 10. Although FIG. 1 shows four sheet wafers 10, the furnace 14 may substantially simultaneously grow fewer or more of the sheet wafers 10. For example, the furnace 14 may grow two wide sheet wafers 10 (also referred to as “crystal sheets 10”).

The housing 16 may include a door 20 to allow access to and inspection of the interior and its components, and one or more optional viewing windows 22. The housing 16 also has an inlet (not shown in FIG. 1, but shown in FIG. 6) for directing feedstock material, such as silicon pellets, into the growth chamber 15 of the housing 16 to the crucible 18. It should be noted that discussion of the silicon feedstock, silicon sheet wafers 10, and argon gas is illustrative and not intended to limit all embodiments of the invention. For example, the sheet wafers 10 may be formed from other materials, e.g., metals, glass, ceramics, or alloys, or using other gasses.

FIG. 2 schematically shows a partially cut away view of a furnace 14 with part of the housing 16 removed. As noted above, the furnace 14 includes the crucible 18 for containing molten material 24 in the interior growth chamber 15 of the housing 16. In one embodiment, the crucible 18 may have a substantially flat top surface that may support or contain the molten material 24 (e.g., molten multi-crystal silicon). Alternatively, other embodiments (not shown) of the crucible 18 may have walls for containing the molten material 24. The crucible 18 includes filament holes (not shown) that allow one or more filaments 12 to pass through the crucible 18. As the filaments 12 pass through the crucible 18, portions of the molten silicon solidify at respective surface menisci (i.e., the liquid-solid interface noted above), thus forming the growing sheet wafer 10 between each respective pair of filaments 12. To facilitate the side-by-side wafer growth, the crucible 18 has an elongated shape with a region for growing sheet wafers 10 in the side-by-side arrangement along its length. Alternative embodiments, however, may grow the wafers 10 in a face-to-face manner.

To at least in part control the temperature profile in its interior, the furnace 14 has insulation that is formed based upon the thermal requirements of the regions in the housing 16. For example, the insulation is formed based on 1) the region containing the molten material 24 (i.e., the crucible 18), and 2) the region containing the resulting growing sheet wafer 10 (the afterheater 28, discussed below and in greater detail in incorporated patent application Ser. No. 13/015,047). To that end, the insulation includes a base insulation 26 that forms an area containing the crucible 18 and the molten material 24, and an afterheater 28 positioned above the base insulation 26 (from the perspective of the drawings).

The afterheater 28 is important to the issue of wafer bow—it is where the just formed wafer 10 cools from very high temperatures toward ambient temperatures. Ideally, the afterheater 28 causes the rate of change of cooling in both the X and Y directions across the wafer 10 to be substantially constant. Again, see the above noted incorporated '047 patent application for more details on various embodiments of the afterheater 28.

In some embodiments, the furnace 14 also may include a gas cooling system that supplies gas from an external gas source (not shown), through a gas cooling manifold, to gas jets 30. The gas cooling system may provide gas to further cool the growing sheet wafer 10 and control its thickness. For example, as shown in FIG. 2, the gas cooling jets 30 may face toward the growing sheet wafer 10 in the area above the crucible 18—toward the above noted meniscus extending from the melt and containing the wafer 10.

To mitigate wafer bow, the furnace 14 has a plurality of wafer guides 32 strategically positioned within its interior. To that end, in each lane of the furnace 14, the wafer guides 32 are positioned very close to, but not too close to, their corresponding meniscus (i.e., close to where the meniscus will be when operating). The wafer guides 32 are positioned to minimize their impact on the temperature profile within the furnace 14 and yet, stabilize the growing wafer 10 as much as possible.

Specifically, FIG. 2 schematically shows a pair of wafer guides 32 configured in accordance with illustrative embodiments of the invention. These wafer guides 32 substantially mechanically retain the growing wafer 10 in its ideal location—near the meniscus extending from the molten material 24. In other words, the wafer guides 32 ideally compensate for downstream mechanical manipulation (of the growing wafer 10) that can move the base of the wafer 10 and thus, the wafer 10 at the meniscus. The wafer guides 32 thus can constrain wafer motion in one or two dimensions—perpendicular and/or parallel to the length of the meniscus. For additional information about the wafer guides 32, see co-pending U.S. patent application No. 61/449,150, naming Brian D. Kernan and Weidong Huang as inventors, the disclosure of which is incorporated herein, in its entirety, by reference.

As noted above, the growth chamber 15 contains pressurized argon or other gas to displace oxygen and other gasses. Although noted as “sealed” above, the growth chamber 15 actually has a number of openings that form leak points for the argon gas. Specifically, the furnace 14 continually moves each growing sheet wafer 10 upwardly, from the crucible 18, and through one of a plurality of chamber openings 17 at the top of the growth chamber 15. Each of these openings 17 thus is a significant point of argon loss and heat loss within the system.

Accordingly, to remedy this problem, the inventors formed a seal 34 across each of the chamber openings 17 to mitigate gas escape into the environment. To that end, in one embodiment, the inventors formed (movable) seals against the growing sheet wafers 10 themselves. More specifically, FIGS. 1 and 2 schematically show four sliding seals 34 positioned across each of the openings 17 and against the growing sheet wafers 10. The openings 17 and seals 34 thus still permit the wafers 10 to move upwardly with very little resistance and yet, at least partially prevent argon from escaping through the openings 17.

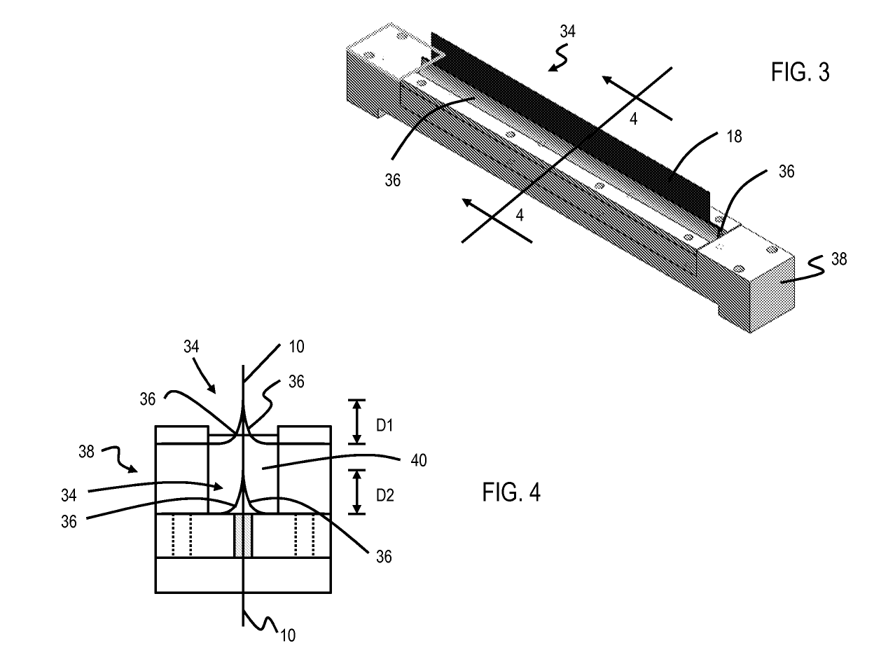

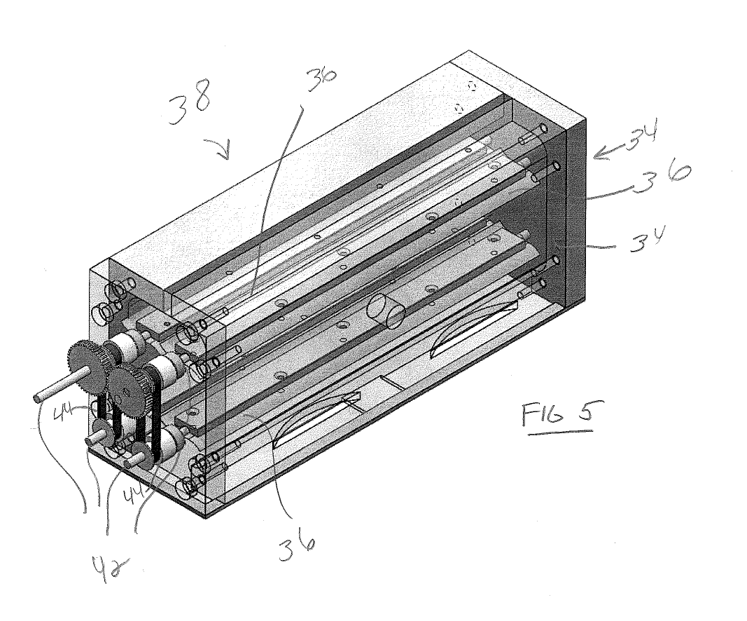

Any number of different seal types may provide the requisite functionality. FIGS. 3 and 4 show details of one type of seal formed across each opening 17. Specifically, the seal 34 preferably is a so-called “tent seal” formed on both sides of the growing wafer 10. This tent seal (also referred to herein using reference number 34) is formed by a first flexible sheet/flap 36 on one side of the wafer 10, and the corresponding second flexible sheet/flap 36 on the other side of the wafer 10. The flexible flaps 36 preferably are fabricated from a material that can withstand high temperatures and apply minimal force to the growing sheet wafer 10. For example, a polyimide sheet, such as KAPTON™, distributed by E.I. du Pont de Nemours and Company of Wilmington, Del., should provide the requisite sealing capability under these conditions. Of course, other types of flexible flaps having the necessary qualities should suffice.

It is anticipated that the tent seal 34 will have a lifespan that is much shorter than that of the furnace 14. Accordingly, as shown in FIG. 3, each tent seal 34 can be a part of a modular seal apparatus (“seal module 38”) that is relatively easily removable from the furnace 14 itself. In other words, the seal module 38 is removably connectible to the furnace 14. For example, the furnace 14 can have a plurality of compartments (not shown) that each receives the seal module 38. During furnace shutdown, the seal module 38 can be removed and replaced with another seal module 38 having new flaps 36. Among other ways, the seal module 38 can be secured in place by any conventional removable connector, such as with a snap fit connection, or with screws.

To deliver further seal efficiency, each chamber opening 17 can have multiple tent seals 34—two or more—longitudinally spaced along the path of the growing sheet wafer 10. FIG. 4 schematically shows a cross-sectional view of this type of redundant seal, which is entirely self-contained within the noted seal module 38. A primary benefit of redundant seals 34—failure of one seal 34 will not necessarily cause wholesale argon gas leakage from the furnace 14.

As shown, each of the two tent seals 34 directly contacts two opposing sides of the growing sheet wafer 10. Ideally, each flap 36 of a single seal 34 applies a very small or negligible amount of force to the growing wafer 10. These forces, applied by two opposing flaps 36, ideally should at worst cancel out and thus, not impact wafer growth. This is very complicated, however, due to the nature of sheet wafer growth; namely, sheet wafers 10 are very thin and very susceptible to bowing (see incorporated patent application No. 61/449,150 above) when cooling within the growth chamber 15. This provides a significant disincentive to forming such a seal 34.

The inventors recognized and overcame this significant impediment to forming a seal 34 across the chamber opening 17. Primarily, they stabilized the sheet wafer 10 within the growth chamber 15 by including the above noted wafer guides 32 within the growth chamber 15. Accordingly, movement of a growing sheet wafer 10 is much more constrained than it would be without the wafer guides 32. In addition, the mounting, dimensions, and materials are selected to cause the flaps 36 to substantially cancel out any opposing forces. For example, both flaps 36 of a single tent seal 34 have approximately the same length, width, and thickness, are formed from substantially the same material, and are geometrically secured within the furnace 14 or seal module 38 in a substantially identical manner.

In illustrative embodiments, the distances D1 and D2, which are the respective distances from the very top of the seal 34 to the bottom of the seal 34, may be between about 0.5 inches and about 1 inch (e.g., about 0.75 inches). As also shown in FIG. 4, a part of each flap 36 illustratively is substantially flush with and slides along the face of the growing sheet wafer 10. For example, this region can be between about 0.0625 inches and about 0.375 inches measured along the longitudinal axis of the growing wafer 10 (i.e., the same direction as D1 and D2). Consistent with the drive toward symmetry, illustrative embodiments ensure that both flaps 36 have a substantially identical amount of their faces flush against the growing wafer 10. In practice, however, this may diverge and require recalibration.

Each tent seal 34 is not expected to provide a complete seal because, by its nature, gas may leak out of its sides. Despite that, the seal 34 should significantly reduce the amount of argon or other gas escaping from the growth chamber 15 via the chamber opening 17. Some embodiments may add further components to reduce that source of leakage from the seal 34.

Redundant seals 34 over the same chamber opening 17 provide additional benefits; namely, this configuration forms a void 40 between the seals 34 that itself acts as a barrier for argon gas escape. For example, some argon gas within the growth chamber 15 may leak into this area, mix with air, to form this additional barrier. In other embodiments, the system may fill the void 40 with a less expensive barrier gas, such as nitrogen. To that end, the seal module 38 may have an integrated nitrogen tank, or inlet for receiving nitrogen gas from an external source.

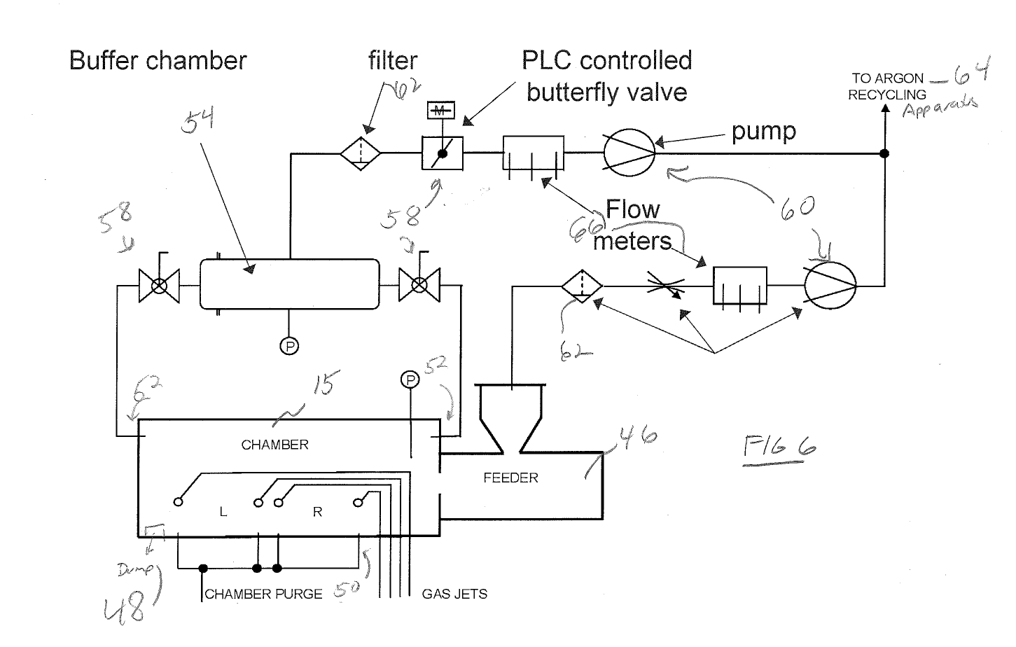

Sheet wafer furnaces 14 typically operate in a “growth cycle” where they produce wafers 10 for a period of time (e.g., 7-10 days), and an “off cycle” for a short period of time for cleaning and maintenance (e.g., 24 hours). In addition, during the growth cycle, one or more lanes in a multilane furnace 14 may require a “re-seeding” process. Specifically, normal growth of one wafer 10 (or more) sometimes becomes interrupted and a new wafer 10 must be seeded to continue the process in that lane. In these cases, primarily during reseeding, the seal 34 can block access to the growth chamber 15. Accordingly, illustrative embodiments mount the tent seal flaps 36 themselves on a movable member. For example, FIG. 5 schematically shows a seal module 38, with redundant tent seals 34, in which each flap 36 is mounted on a rotatable shaft 42 or a hinge. As shown, a first belt 44 connects the two flaps 36 on one side of the sheet wafer 10, while a second belt 44 connects the two flaps 36 on the other side of the sheet wafer 10. An operator therefore may manually rotate the shafts 42 during an off cycle or receiving operation.

Alternatively, the furnace 14 may have control logic and motors (not shown) that rotate the shafts 42 in a desired manner automatically upon receipt of a stimulus, such as when an operator pushes a prescribed button on the furnace 14. For example, the furnace 14 can have an open button to open all of the tent seals 34, and a corresponding close button to close all the tent seals 34. Other embodiments further may control individual flaps 36, or selected groups of flaps 36 (e.g., flaps 36 on one side of the growing wafer 10).

As noted above, some embodiments use other techniques for moving the flaps 36. For example, rather than using a rotating shaft 42, the seal module 38 may have a mechanism for simply sliding the flaps 36 away from their nominal rest position.

During normal operation, a prior art furnace 14 may use about 40 liters per minute of argon. Illustrative embodiments having the seals 34 are expected to reduce that amount of argon use to between about 15 and 25 liters per minute (e.g., about 20 liters per minute). Reduced argon use thus should correspondingly reduce the cost of producing sheet wafers 10.

To further reduce argon use, the furnace 14 may be part of a larger argon recycling system that receives, processes, and reuses argon that once was part of the wafer growth process within the interior of the growth chamber 15. FIG. 6 schematically shows the sheet wafer furnace 14 within an argon recycling system. Although preferred embodiments include the above noted seal 34 over the chamber opening(s) 17 of the furnace 14, some embodiments may use a furnace 14 without such a seal 34. Accordingly, discussion of the furnace 14 having a seal 34 is not intended to limit all embodiments.

The system has the above-noted growth chamber 15 that receives silicon feedstock from a feeder 46, and a melt dump region 48 for removing or dumping less pure silicon. For more information regarding melt dumping, see copending U.S. patent application Ser. No. 11/741,372, filed Apr. 27, 2007, and naming David Harvey, Weidong Huang, Richard Wallace, Leo van Glabbeek, and Emanuel Sachs as inventors, the disclosure of which is incorporated herein, in its entirety, by reference. In addition, the furnace 14 also has the above noted gas jets 30 for cooling the growing wafer 10, and additional gas inlets 50 for feeding argon gas into the growth chamber 15 as discussed above.

Illustrative embodiments did not simply release of the argon gas into the environment. Instead, unlike many prior art furnaces, the growth chamber 15 also has a plurality of low resistance gas outlets 52 fluidly connected to a buffer chamber 54. Among other things, the buffer chamber 54 may be a stainless steel vessel fluidly connected with the growth chamber 15 through a series of pipes 56 and isolation valves 58.

A downstream pump 60 draws the argon gas from the buffer chamber 54, through a filter 62 and toward an argon recycling apparatus 64. To ensure that the argon may be recycled, the argon gas should be substantially pure. For example, impurities within the argon gas should not exceed 10% of the total gas directed toward the recycling apparatus 64. Accordingly, the filter 62 should remove some impurities. Flow meters 66 between the filter 62 and the pump 60 monitor gas flow rates, while a simple butterfly valve 58 (or other type of valve) controls gas flow toward the argon recycling apparatus 64.

Although not shown in this manner, the overall system may be a closed loop and thus, direct recycled gas back into the growth chamber 15. Other embodiments, however, are an open loop system, directing gas only toward the recycling apparatus 64.

The feeder 46 also should be filled with argon gas to displace oxygen and other impurities in the system. Accordingly, another set of pipes 56, flow meters 66, pumps 60, and filters 62 also directs argon from the feeder 46 and toward the argon recycling apparatus 64 in the same manner as the corresponding components associated with the buffer chamber 54.

In illustrative embodiments, the pressure of the argon gas within the growth chamber 15 remains substantially constant (i.e., within a very narrow pressure range) throughout the wafer growth process. In illustrative embodiments, this constant pressure is a positive pressure that is high enough to prevent gas impurities, such as oxygen, from entering the growth chamber 15.

This pressure should be balanced, however, to minimize the amount of argon gas required for the process. The buffer chamber 54 maintains this constant pressure by permitting the pumps 60 to draw the argon gas directly from its interior without significantly impacting the pressure within the growth chamber 15. Without the buffer chamber 54, the pumps 60 would draw the gas directly from the growth chamber 15, which the inventors believe would risk reducing the pressure below atmospheric pressure, drawing oxygen toward the growing wafers 10. This undesirable result would adversely impact the quality of the growing wafers 10.

Accordingly, during startup, the system begins purging oxygen and other impurities from the growth chamber 15 and feeder 46. During that process, the isolation valves 58 to the buffer chamber 54 are closed, ensuring that the buffer chamber 54 has negligible amounts of impurities. The buffer chamber 54 may be in a vacuum state or have substantially pure argon at that time. After purging the growth chamber 15 and feeder 46, the system opens the isolation valves 58 to the buffer chamber 54, and pumps argon toward the argon recycling apparatus 64 from the feeder 46 and the buffer chamber 54.

The system then may produce sheet wafers 10 in its normal manner. Specifically, in one embodiment, the furnace 14 may cut a growing sheet wafer 10 (e.g., with a movable laser), remove the cut portion, and continue to draw the growing wafer 10 from the crucible 18 until it is cut again. During this period of time, the argon pressure within the growth chamber 15 should remain substantially constant. In other words, the argon gas pressure should be substantially constant during at least a part of the wafer growth process—preferably during the entire wafer growth cycle.

Although the above discussion discloses various exemplary embodiments of the invention, it should be apparent that those skilled in the art can make various modifications that will achieve some of the advantages of the invention without departing from the true scope of the invention.

What is claimed is:

1. A sheet wafer furnace comprising:
a chamber having an opening;
a crucible within the chamber and spaced from the opening,
a puller configured to pull a sheet wafer from molten material in the crucible and through the opening in the chamber; and
a seal across the opening of the chamber.

2. The sheet wafer furnace as defined by claim 1 wherein the seal comprises a first set of flaps that cooperate to form a first seal.

3. The sheet wafer furnace as defined by claim 2 wherein the seal comprises a second set of flaps that cooperate to form a second seal, the second set of flaps being closer to the crucible than the first set of flaps.

4. The sheet wafer furnace as defined by claim 3 wherein the first set of flaps and the second set of flaps form a void therebetween when the first and second seal are closed, the void containing a gas.

5. The sheet wafer furnace as defined by claim 4 wherein the gas comprises nitrogen.

6. The sheet wafer furnace as defined by claim 2 wherein the flaps are flexible.

7. The sheet wafer furnace as defined by claim 6 wherein the flaps comprise polyimide.

8. The sheet wafer furnace as defined by claim 1 further comprising a cartridge comprising the seal, the cartridge being removably connectible across the opening.

9. The sheet wafer furnace as defined by claim 1 further comprising a hinge secured to the seal, the hinge being movable to open the seal.

10. The sheet wafer furnace as defined by claim 9 wherein the hinge is coupled with a motor configured to control opening and closing of the seal.

11. The sheet wafer furnace as defined by claim 1 wherein the seal comprises a tent seal.

12. The sheet wafer furnace as defined by claim 1 further comprising a wafer guide spaced from the top surface of the crucible and within the chamber, the wafer guide forming a channel for passing a growing sheet wafer.

13. The sheet wafer furnace as defined by claim 12 further comprising an afterheater region for controlling the temperature within the interior chamber, the wafer guide being at least in part within the afterheater region.

14. The sheet wafer furnace as defined by claim 12 wherein the wafer guide comprises a plurality of posts extending from at least two opposing surfaces of the afterheater.

15. The sheet wafer furnace as defined by claim 1 wherein the seal comprises members on two sides of the opening each provide a generally radially inward force at a contact point, the members applying a net neutral force at the contact point.

16. A method of growing a sheet wafer, the method comprising:
melting molten material in a crucible within a chamber, the chamber having a opening; and
drawing a sheet wafer from the molten material in the crucible and through the opening, the opening having a seal that contacts two sides of the sheet wafer at a contact point on each side of the sheet wafer,
the seal forming a sliding seal along the sheet wafer.

17. The method as defined by claim 16 further comprising directing a gas into the chamber.

18. The method as defined by claim 17 wherein the gas comprises argon.

19. The method as defined by claim 16 wherein the seal wherein the seal comprises a first set of flaps that cooperate to form a first seal.

20. The method as defined by claim 19 wherein the seal comprises a second set of flaps that cooperate to form a second seal, the second set of flaps being closer to the crucible than the first set of flaps.
